(19) United States
(12) Patent Application Publication
(10) Pub. No.: US 2005/0085087 A1
(43) Pub. Date: Apr. 21, 2005

(54) Plasma processing method, plasma etching method and manufacturing method of solid-state image sensor

(75) Inventors: Mitsuru Okigawa, Nagoya-shi (JP); Seiji Samukawa, Sendai-shi (JP)

Correspondence Address: Barry E. Bretschneider;Morrison & Foerster LLP, Suite 300, 1650 Tysons Boulevard, McLean, VA, 22102, US

(73) Assignees: Sanyo Electric Co., Ltd., Moriguchi-city (JP); Seiji SAMUKAWA, Sendai-shi (JP)

(21) Appl. No.: 10/924,263

(22) Filed: Aug. 24, 2004

(30) Foreign Application Priority Data
Aug. 25, 2003 (JP) 2003-300256

(51) Int. Cl. H01L 21/00; H01L 21/84; H01L 21/302; H01L 21/461

(52) U.S. Cl. 438/710

(57) ABSTRACT

A method of plasma processing is offered to suppress generation of interface states, specifically to suppress increase in the dark current of a solid-state image sensor by reducing the interface states. An interlayer insulation film made of silicon nitride film is formed over a silicon substrate by plasma CVD, and a photoresist layer is selectively formed on the interlayer insulation film. Subsequent heating process makes a profile of the photoresist layer round. Next, the interlayer insulation film is plasma-etched using the photoresist layer as a mask and a fluorocarbon gas as an etching gas to form micro lenses. Pulse-time-modulated plasma method in which RF power is supplied intermittently is used to suppress increase in the interface states at silicon-silicon dioxide interface due to an influence of UV light generated in the plasma etching.

### CROSS-REFERENCE OF THE INVENTION

This invention is based on Japanese Patent Application No. 2003-300256, the content of which is incorporated herein by reference in its entirety.

### BACKGROUND OF THE INVENTION

1. Field of the Invention

This invention relates to a method of plasma processing, a method of plasma etching and a method of manufacturing solid-state image sensors using plasma etching, specifically to a technology to reduce interface states induced by plasma processing.

2. Description of the Related Art

Solid-state image sensors such as CCDs (Charge Coupled Devices) and MOS image sensors are used in digital cameras and other video equipment in recent years. In a manufacturing process of the solid-state image sensors, the plasma processing is used in etching an insulation film formed on a silicon substrate and in depositing various kinds of films.

Plasma used in the plasma processing is accompanied with generation of UV (ultraviolet) light since the plasma is generated by gas discharge in a vacuum.

When the solid-state image sensor such as the CCD is radiated with the UV light, interface states at an interface between a semiconductor and an insulation film, i.e. interface states at a Si-SiO₂ interface for example, increase in number. As a result, a so-called dark current is induced by thermal electrons which are stimulated from a valence band to a conduction band through the interface states. An effect of the dark current is a noise in a signal appeared on a display screen, causing deterioration in quality of the display.

Further information on an increase in the dark current of the CCD due to the plasma irradiation (Ar, He, O₂) is provided in, for example, Japanese Journal of Applied Physics, Vol. 42 (2003) pp. 2444-2448.

This invention is directed to a method of plasma processing which suppresses the generation of the interface states, specifically to suppress the increase in the dark current of the solid-state image sensor by reducing the interface states.

### SUMMARY OF THE INVENTION

The invention provides a method for a plasma processing. The method includes providing a vacuum chamber, introducing a gas comprising a fluorocarbon gas into the vacuum chamber, and supplying intermittently an RF power for generating plasma to the vacuum chamber.

The invention also provides a method for a plasma etching of an insulation film formed on a semiconductor wafer. The method includes placing the semiconductor wafer in a vacuum chamber, introducing an etching gas comprising a fluorocarbon gas into the vacuum chamber, and supplying intermittently an RF power for generating plasma to the vacuum chamber.

The invention further provides a method of manufacturing a semiconductor device. The method includes forming a solid-state image sensor on a surface of a semiconductor wafer, forming an insulation film over the solid-state image sensor, forming a patterned photoresist layer on the insulation film, and plasma-etching the insulation film using the patterned photoresist layer as a mask to form a lens on the solid-state image sensor. The plasma-etching uses an etching gas comprising a fluorocarbon gas, and an RF power is supplied intermittently to generate plasma for the plasma-etching.

### BRIEF DESCRIPTION OF THE DRAWINGS

FIG. 1 is a plan view showing an image pick up portion of a frame transfer type CCD according to an embodiment of this invention.

FIG. 2 is a cross-sectional view showing section X-X in FIG. 1.

FIGS. 3A, 3B and 3C are cross-sectional views showing manufacturing process steps of micro lenses of the CCD according to the embodiment of this invention.

FIG. 4 shows a configuration of plasma etching apparatus according to the embodiment of the invention.

FIG. 5 is a cross-sectional view showing a measurement system to measure a dark current in the CCD.

FIG. 6 shows a result of dark current measurement in the CCD with the measurement system shown in FIG. 5.

FIG. 7A shows measured charge pumping currents of a MOSFET after the plasma etching.

FIG. 7B shows the MOSFET and a circuit structure to evaluate interface states with charge pumping method.

FIG. 8 shows emission spectra from fluorocarbon-oxygen gas-mixture plasma.

FIG. 9 shows a correlation between charge pumping current increase and 200 to 350 nm UV light intensity.

FIGS. 10A and 10B show effect of TM (pulse-time-modulated) plasma on CCD dark current in comparison with CW (continuous wave) plasma.

### DETAILED DESCRIPTION OF THE INVENTION

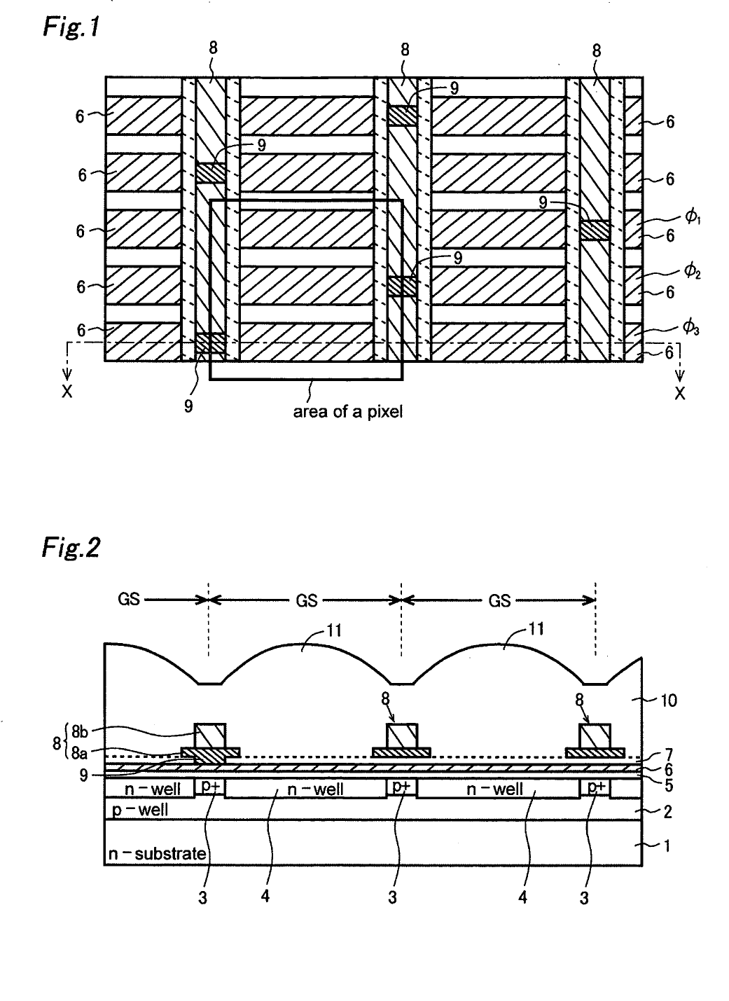

Next, an embodiment of this invention will be described referring to figures hereinafter. First, a structure of an image pick up portion of a CCD of this embodiment is applied will be explained referring to FIG. 1 and FIG. 2. FIG. 1 is a plan view showing the image pick up portion of the frame transfer type CCD and FIG. 2 is a cross-sectional view showing section X-X in FIG. 1.

A p-type well 2 is formed in a surface of an n-type silicon substrate 1. P+-type isolation regions 3 doped with high concentration of p-type impurities are formed in a surface of the p-type well 2 being separated from each other. An n-type well 4 is formed in each of spacing between the p+-type isolation regions 3. The n-type well 4 makes a channel region which serves as a transfer path for electric charges of information.

Each of a plurality of transfer gate electrodes 6 made of phosphor-doped polysilicon is formed on each of a plurality of the n-type wells 4 through a gate insulation film 5 made of a silicon dioxide (SiO₂) film or stacked films of a silicon dioxide film and a silicon nitride (Si₃N₄) film. Three phases of frame transfer clocks Φ1, Φ2 and Φ3 are applied to the transfer gate electrodes 6 through transfer clock supply lines 8, which will be described later, to control electric potential of the n-type wells 4, which serve as channel regions, accordingly to the clocks.

A plurality of the clock supply lines 8 is formed on the transfer gate electrodes 6 extending in an orientation to cross the transfer gate electrodes 6 through a first interlayer insulation film 7 made of a silicon dioxide film or a silicon nitride film. Each of the transfer clock lines 8 is made of a layer of polysilicon and a layer of refractory metal (tungsten, for example) stacked on the layer of polysilicon.

The transfer clock lines 8 are connected to the transfer gate electrodes 6 through contact holes 9 formed in the first interlayer insulation film 7. And a second interlayer insulation film 10 is formed to cover the transfer clock lines 8. After plasma-etching the second interlayer insulation film 10, a plurality of micro lenses 11 are formed on a surface of the second interlayer insulation film 10. Each of the micro lenses 11 is formed in each of pixel areas GS of the image pick up portion of the CCD, respectively.

A pixel area GS includes three transfer gate electrodes 6, each of which is provided with each of the frame transfer clocks Φ1, Φ2 and Φ3 respectively, and an area surrounded by two adjacent p+-type isolation regions 3. During reception of light, only the transfer gate electrode 6 provided with Φ2 is turned on while the other two transfer gate electrodes provided with Φ1 and Φ3 are turned off in order to prevent the electric charges of information in the pixel from mixing up with those in adjacent pixels. The micro lens 11 is formed so as to converge the light to the transfer gate electrode 6 provided with Φ2 during reception of the light.

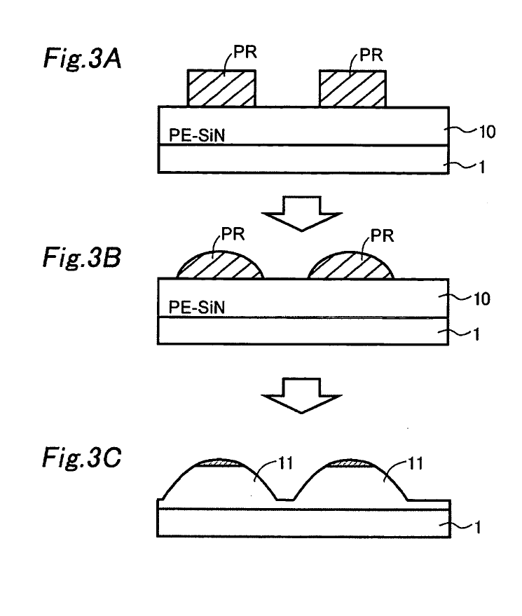

Next, a method to form the micro lenses 11 by plasma etching will be explained referring to figures. FIGS. 3A, 3B and 3C are cross-sectional views showing the manufacturing process of micro lenses of the CCD. The figures schematically show components to form the micro lenses only, and the rest of components shown in FIG. 2 are omitted.

The second interlayer insulation film 10 made of silicon nitride film is formed over the silicon substrate 1 by plasma CVD, and a photoresist layer PR is selectively formed on the second interlayer insulation film 10, as shown in FIG. 3A. At this point, the silicon dioxide film which is part of the gate insulation film 5 is formed on the silicon substrate 1 as shown in FIG. 2. Accordingly, an interface between the silicon substrate and the silicon dioxide film exists.

Subsequent heating process makes a profile of the photoresist layer PR round, as shown in FIG. 3B. Then the second interlayer insulation film 10 is plasma-etched using the photoresist layer PR as a mask and a fluorocarbon gas as an etching gas to form the micro lenses 11.

In the plasma etching, balancing deposition of CF₂ generated from the fluorocarbon gas and etching of silicon nitride which makes the second interlayer insulation film 10 is important to obtain a desired profile of the micro lenses. Mixture of oxygen gas and one of the fluorocarbon gases, i.e. C₄F₈, C₂F₄, CF₄, CF₃I and so on, is appropriate as the etching gas. O₂ gas is added for ashing and gradual removing of the photoresist layer PR. Among the fluorocarbon gases, C₄F₈ gas is most effective in controlling the profile of the micro lenses because it produces more CF₂ molecules than the other fluorocarbon gases. CF₃I gas is another gas with which electrons, fluorocarbon ions and CF₂ radicals contribute to the etching, as with the other gases mentioned above.

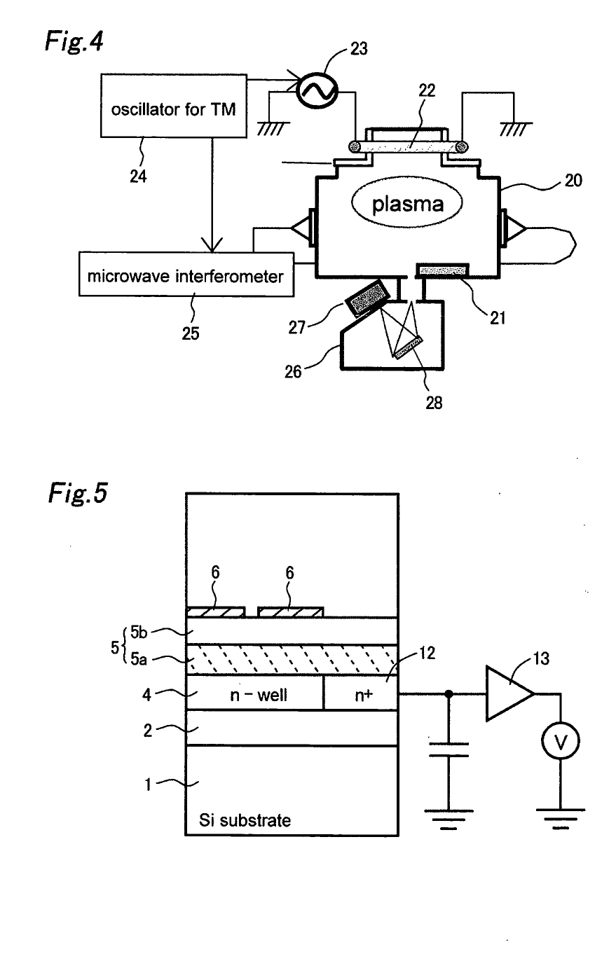

TM (pulse-time-modulated) plasma is used to suppress an increase in the number of the interface states at the interface between the silicon substrate and the silicon dioxide film induced by UV light generated during the plasma etching. RF power is supplied intermittently to generate the TM plasma. Details will be explained hereafter, referring to FIG. 4.

FIG. 4 shows a configuration of plasma etching apparatus capable of generating the TM plasma. The specimen of this etching experiment, which is a silicon wafer 21 having CCDs and MOSFETs for monitoring the interface states, is placed on a stage at a bottom of a vacuum chamber 20 and a one-turn antenna 22 for inductively coupled plasma is attached to an upper portion of the vacuum chamber 20, as shown in FIG. 4.

The RF power of 13.56 MHz is supplied from an RF power supply 23 to the one-turn antenna 22 intermittently. An output of an oscillator 24 for pulse-time modulation controls the supply of the RF power from the RF power supply 23. The generation of plasma is turned off when the supply of the RF power from the RF power supply 23 is stopped, and turned on when the supply of the RF power is re-started. This on-off cycle is repeated. The plasma is generated for 180 seconds with plasma on time of 50 μs and off time of 50 μs in this embodiment. However, this embodiment is not limited to the conditions described above.

A microwave interferometer 25 shown in FIG. 4 measures electron density in the plasma generated in the vacuum chamber 20. A VUV (Vacuum Ultraviolet) spectrometer 26 is equipped with a photomultiplier tube 27 and a grating 28.

The silicon wafer 21 is placed in the vacuum chamber 20 supplied and the fluorocarbon gas is supplied into the vacuum chamber 20. The plasma is intermittently generated to perform plasma etching by providing the one-turn antenna 22 with the RF power of 13.56 MHz intermittently from the RF power supply 23.

FIG. 5 is a cross-sectional view showing a measurement system to measure the dark current in the CCD after the plasma etching. FIG. 5 corresponds to a cross-sectional view showing a section perpendicular to the section X-X in FIG. 1. The gate insulation film 5 is formed of a silicon dioxide (SiO₂) film 5a of 62 nm and a silicon nitride (Si₃N₄) film 5b of 75 nm in the embodiment, as shown in FIG. 5. An n+-type layer 12 contacting the n-type well 4 which makes the channel region is formed and connected to an amplifier 13. The dark current in the CCD can be measured by reading an output of the amplifier 13.

Characteristics of the CCD dark current and the interface states will be described in detail hereinafter referring to figures.

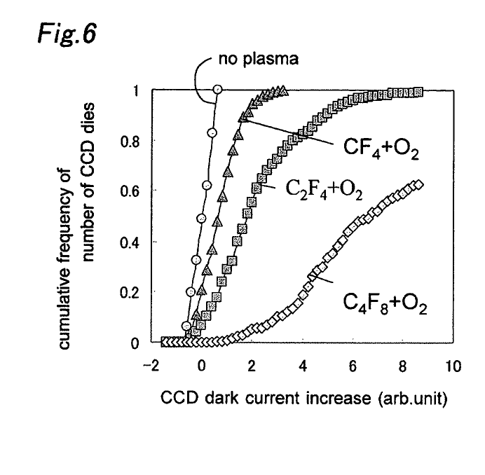

FIG. 6 shows the CCD dark current after the plasma etching measured with the measurement system shown in FIG. 5. The plasma etching is made not by TM plasma etching but by CW (continuous wave) plasma etching in which the RF power is supplied continuously. A horizontal axis represents increase in the dark current in arbitrary unit, while a vertical axis represents cumulative frequency of number of CCD dies in the silicon wafer 21.

This cumulative frequency of number of CCD dies is defined as a ratio of the number of dies on a wafer that have a dark current value lower than or equal to a specified value to the total number of the dies on the wafer. For example, with respect to the C₂F₄+O₂ gas mixture, the ratio of the dies having the dark current equal to or lower than “2” is about 0.5, half of the dies on the wafer.

Oxygen gas mixtures with CF₄, C₂F₄ and C₄F₈ are used in this experiment. Electron density of each plasma is 5.5×10¹⁰ cm⁻³, pressure is 20 mTorr, a flow rate of each fluorocarbon gas is 50 sccm and a flow rate of O₂ gas is 15 sccm. In order to make the electron density of each plasma 5.5×10¹⁰ cm⁻³, the RF power is set at 1.1 kW for CF₄+O₂, 850 W for C₂F₄+O₂ and 1.2 kW for C₄F₈+O₂. The dark current is measured at 60° C. As the figure clearly shows, the increase in the dark current is largest for C₄F₈+O₂, next for C₂F₄+O₂ and least for CF₄+O₂. Though C₄F₈ gas offers best control over the profile of the micro lenses 11, it induces the largest CCD dark current increase (about seven times as large as with CF₄).

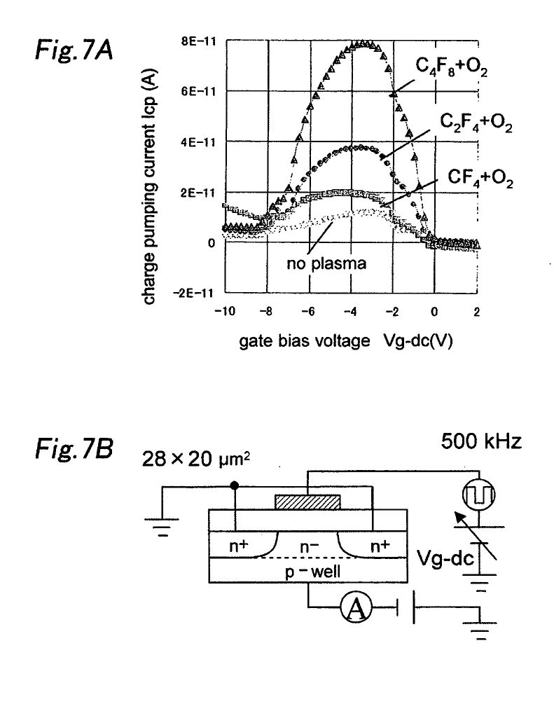

FIGS. 7A and 7B show a charge pumping current of the MOSFET after the plasma etching. The plasma etching is also made not by TM plasma etching but by CW plasma etching in which the RF power is supplied continuously. A horizontal axis represents a gate bias voltage of the MOSFET, while a vertical axis represents the charge pumping current in FIG. 7A. The charge pumping current reflects the density of the interface states at the Si-SiO₂ interface induced by CF₄, C₂F₄ and C₄F₈ plasma. FIG. 7B shows the MOSFET and a circuit structure to evaluate the interface states with charge pumping method. Increase in the interface states estimated from the charge pumping current shown in FIG. 7A is analogous to the increase in the dark current shown in FIG. 6. That is, C₄F₈+O₂, C₂F₄+O₂ and CF₄+O₂.are arranged in order of an amount of increase in the interface states. CF₃I+O₂ is also evaluated and appeared to have about the same value as CF₄+O₂, although it is not shown in the figure.

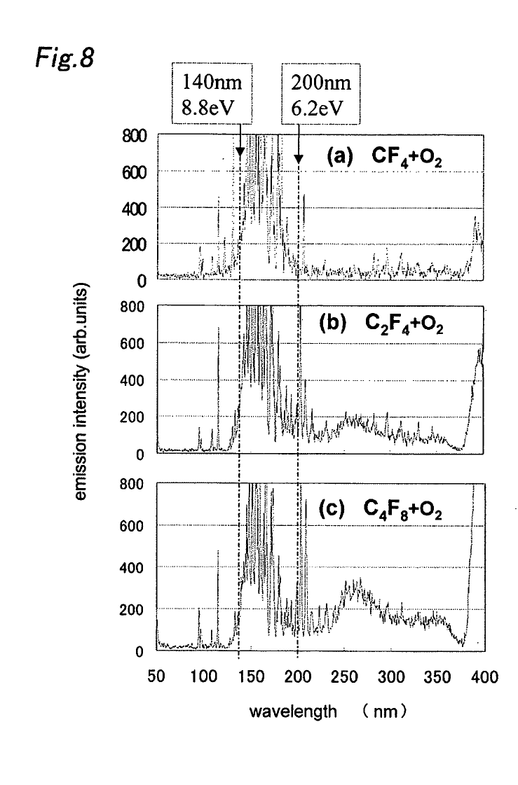

FIG. 8 shows emission spectra from fluorocarbon-oxygen gas-mixture plasma. The electron density of the plasma is 5.5×10¹⁰ cm⁻³. The figure suggests that these spectra depend on the kinds of gases used. CF₄, C₂F₄ then C₄F₈ are arranged in order of VUV light intensity under 140 nm. This means that as the gas molecular becomes smaller, the VUV light intensity under 140 nm becomes larger. On the other hand, in terms of the UV light from 200 to 350 nm attributed to CF₂ molecules, C₄F₈ has the highest intensity of the UV light while CF₄ has the lowest of the three.

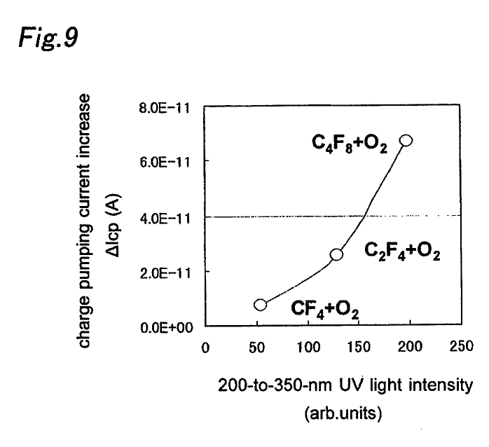

FIG. 9 shows a correlation between charge pumping current increase ΔIcp (interface states) and the UV light intensity between 200 and 350 nm. FIG. 9 is derived from results of FIG. 7A and FIG. 8. A horizontal axis represents an integral from 200 nm to 350 nm of emission intensity with respect to wavelength, while a vertical axis represents charge pumping current increase ΔIcp. A positive correlation is observed between damage to the CCD by the plasma, that is, the increase in the CCD dark current and the increase in the interface states and the over-200 nm UV light intensity. This strongly suggests that UV light from 200 to 350 nm emitted from CF2 molecules induces interface states at the silicon-silicon dioxide interface resulting in increased CCD dark current.

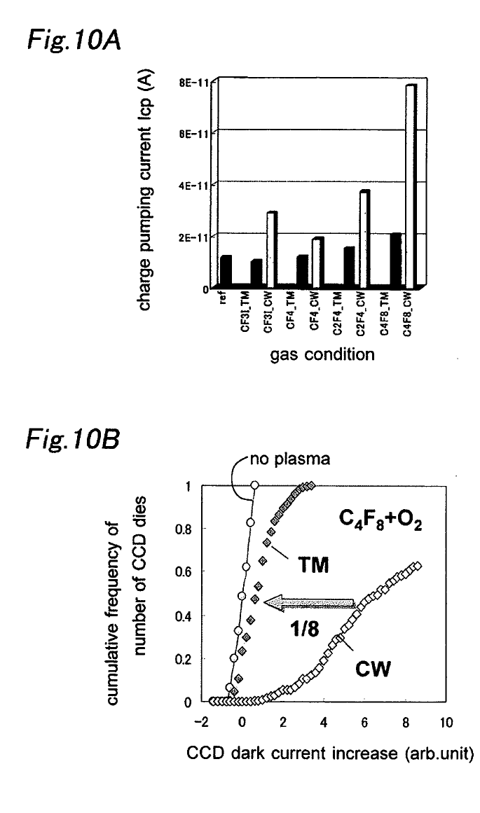

FIGS. 10A and 10B show effect of TM (pulse-time-modulated) plasma on the charge pumping current and the increase in the CCD dark current in comparison with CW (continuous wave) plasma. FIG. 10A shows a comparison of charge pumping current using CW plasma and TM plasma. By using TM plasma, the charge pumping current decreases for all kinds of gases used, i.e. CF₃I, CF₄, C₂F₄ and C₄F₈, as seen from the figure. C₄F₈ produces the largest decrease in the charge pumping current, i.e., ¼ compared with CW plasma.

FIG. 10B shows reduction in the CCD dark current for C₄F₈ gas. Using TM plasma reduces the CCD dark current to ⅛ compared with using CW plasma.

UV light emission which induces the dark current is considered to be caused by transition of molecules from excitation state to non-excitation state due to collisions of electrons with the molecules. Since the RF power is supplied intermittently in TM plasma method, it is considered that the collisions between the electrons and the molecules do not occur during periods in which the supply of the RF power is stopped, resulting in suppression of UV light emission. On the other hand, etching performance is maintained even during the periods in which the supply of the RF power is stopped, since the electrons and ions of fluorocarbon as well as CF₂ radicals remain in the plasma and contribute the etching. As a result, the increase in the interface states and increase in the CCD dark current can be suppressed while maintaining the etching performance of C₄F₈ gas according to the embodiment.

The formation of micro lenses 11 of the CCD by the plasma etching is described in this embodiment. However, this embodiment is not limited to the above, but also applicable to other etching processes using fluorocarbon gas, that is, forming contact hole 9 shown in FIG. 2, etching a sidewall spacer of the MOSFET and etching an insulation film in damascene process, for example. This embodiment can be applied not only to CCD, but also to MOS image sensors, with which reduction in interface states and the dark current is expected.

Although the plasma etching is described in the embodiment, this invention can be also applied to plasma CVD using the fluorocarbon gas as a gas for deposition. Since the UV light is generated in the plasma CVD as in the plasma etching, the reduction in the number of the interface states and the dark current is expected to be obtained by applying the TM plasma method.

Accordingly, the number of the interface states at semiconductor-insulator interface in a plasma process can be suppressed. Specifically, when solid-state image sensors, such as CCDs and CMOS image sensors, are manufactured, the quality of the display is improved.

1. A method for a plasma processing, comprising:
providing a vacuum chamber;
introducing a gas comprising a fluorocarbon gas into the vacuum chamber; and
supplying intermittently an RF power for generating plasma to the vacuum chamber.

2. The method of claim 1, wherein the fluorocarbon gas is CF₄ gas, C₂F₄ gas, C₄F₈ gas, CF₃I gas or a mixture thereof.

3. The method of claim 1, further comprising introducing a silicon wafer on which a solid-state image sensor is formed into the vacuum chamber for the plasma processing.

4. The method of claim 2, further comprising introducing a silicon wafer on which a solid-state image sensor is formed into the vacuum chamber for the plasma processing.

5. A method for a plasma etching of an insulation film formed on a semiconductor wafer, comprising:
placing the semiconductor wafer in a vacuum chamber;
introducing an etching gas comprising a fluorocarbon gas into the vacuum chamber; and
supplying intermittently an RF power for generating plasma to the vacuum chamber.

6. The method of claim 5, wherein the fluorocarbon gas is CF₄ gas, C₂F₄ gas, C₄F₈ gas, CF₃I gas or a mixture thereof.

7. The method of claim 5, wherein the etching gas further comprises oxygen gas, and the fluorocarbon gas is CF₄ gas, C₂F₄ gas, C₄F₈ gas, CF₃I gas or a mixture thereof.

8. The method of claim 5, wherein the semiconductor wafer comprises a solid-state image sensor formed thereon.

9. The method of claim 6, wherein the semiconductor wafer comprises a solid-state image sensor formed thereon.

10. The method of claim 7, wherein the semiconductor wafer comprises a solid-state image sensor formed thereon.

11. A method of manufacturing a semiconductor device, comprising:
forming a solid-state image sensor on a surface of a semiconductor wafer;
forming an insulation film over the solid-state image sensor;
forming a patterned photoresist layer on the insulation film; and
plasma-etching the insulation film using the patterned photoresist layer as a mask to form a lens on the solid-state image sensor,
wherein the plasma-etching uses an etching gas comprising a fluorocarbon gas, and an RF power is supplied intermittently to generate plasma for the plasma-etching.

12. The method of claim 11, wherein the fluorocarbon gas is CF₄ gas, C₂F₄ gas, C₄F₈ gas, CF₃I gas or a mixture thereof.

13. The method of claim 11, wherein the etching gas further comprises oxygen gas, and the fluorocarbon gas is CF₄ gas, C₂F₄ gas, C₄F₈ gas, CF₃I gas or a mixture thereof.
